(19) United States
(12) Patent Application Publication
(10) Pub. No.: US 2019/0145926 A1
(43) Pub. Date: May 16, 2019

(54) WAFER LEVEL GATE MODULATION ENHANCED DETECTORS

(71) Applicant: STC. UNM, Albuquerque, NM (US)

(72) Inventors: Sanjay KRISHNA, Albuquerque, NM (US); Payman ZARKESH-HA, Albuquerque, NM (US); David A. RAMIREZ, Albuquerque, NM (US); Brianna KLEIN, Albuquerque, NM (US); Francesca CAVALLO, Albuquerque, NM (US); Seyedeh Marziyeh ZAMIRI, Albuquerque, NM (US); Alireza KAZEMI, Albuquerque, NM (US); Clark KADLEC, Albuquerque, NM (US)

(21) Appl. No.: 16/097,481

(22) PCT Filed: Mar. 21, 2017
(86) PCT No.: PCT/US2017/023424

§ 371 Date: Oct. 29, 2018

Related U.S. Application Data
(60) Provisional application No. 62/329,668, filed on Apr. 29, 2016.

(51) Int. Cl. G01N 27/414; H01L 29/20; H01L 31/113; H01L 31/0304; H01L 31/18

(52) U.S. Cl. CPC G01N 27/414; H01L 29/20; H01L 31/184; H01L 31/0304; H01L 31/1136

(57) ABSTRACT

A detector or sensor including a transistor having a sensor element that generates a current when exposed to a stimulus such as light or a chemical, in one implementation, the sensor element is positioned between a transistor gate and a transistor channel. When the sensor element is not being exposed to the stimulus, the transistor outputs a first voltage on a transistor drain contact when the transistor inverts. When the sensor element is being exposed to the stimulus, the transistor outputs a second voltage on the transistor drain contact when the transistor inverts, where the second voltage is higher than the first voltage.

### PRIORITY

This application claims the benefit of U.S. Provisional Application No. 62/329,668, filed Apr. 29, 2016, which is incorporated herein by reference as if set forth in its entirety.

### TECHNICAL FIELD

The present teachings relate to the field of sensors such as photosensors, chemical sensors, etc., and, more particularly, to sensor structures and fabrication methods.

### BACKGROUND

Detectors and sensors are used in a variety of applications in fields such as defense, security, manufacturing, metrology, energy efficiency and monitoring, environmental monitoring, automation, robotics, health, and many others. For sensing applications, detectors may be provided as a single pixel sensor or as a small format array. For imaging applications, detectors may be incorporated into focal plane arrays (FPAs). One type of FPA includes photosensitive elements that are bonded through indium bumps to a silicon circuitry. The photosensitive elements may produce a photovoltage, which is sensed by a readout integrated circuit (ROIC) formed using a silicon substrate. Typical FPAs based on photonic detectors involve wafer level processing of the photosensitive element followed by dicing of the arrays, particularly for photodetectors sensitive in the infrared and terahertz bands.

To form these photodetectors, a plurality of photodetector dies and a plurality of ROIC dies may be separately manufactured in wafer form using wafer-level fabrication techniques. A photodetector wafer and a ROIC wafer are each formed and diced to form a plurality of individual photodetector dies and a plurality of individual ROIC circuits. Each photodetector is flip-chip bonded to an ROIC to form a complete photosensor chip. Prior to use, the photosensor chip may undergo further processing, such as removal of the substrate, packaging, testing, and operational characterization.

### SUMMARY

The following presents a simplified summary in order to provide a basic understanding of some aspects of one or more implementations of the present teachings. This summary is not an extensive overview, nor is it intended to identify key or critical elements of the present teachings, nor to delineate the scope of the disclosure. Rather, its primary purpose is merely to present one or more concepts in simplified form as a prelude to the detailed description presented later.

A sensor according to an implementation of the present teachings includes a transistor having a transistor source, a transistor drain, a transistor channel positioned between the transistor source and the transistor drain, and a transistor gate positioned over the transistor channel. The sensor further includes a sensor element positioned between the transistor gate and the transistor channel. The sensor element is configured to generate an electric current when exposed to a stimulus. The sensor is configured such that a first electric current output by the transistor when the sensor element is exposed to the stimulus is different than a second electric current output by the transistor when the sensor element is not exposed to the stimulus.

The electric current generated by the sensor element results from the exposure to the stimulus. Further, the transistor drain may have a first output when a threshold voltage is applied to the transistor and the sensor element is not being exposed to the stimulus, and the transistor drain may have a second output when the threshold voltage is applied to the transistor and the sensor element is being exposed to the stimulus, wherein the second output is larger than the first output. The sensor element may be a III-V semiconductor, where the senor may be configured to sense photonic radiation. In an implementation, the sensor element may have a thickness of from 10 nanometers to 50 microns, and the transistor gate has a thickness of from 1 nanometer to 10 microns. The transistor gate may be configured for passage of the stimulus therethrough during operation of the transistor.

The sensor element may include at least one of a hydrophilic sensor element or a hydrophobic sensor element, and the sensor may be configured to sense a chemical. The sensor element may be a III-V semiconductor, and the sensor may be configured to sense a hydrophobic chemical reagent or a hydrophilic chemical reagent.

In an implementation, the transistor may be an enhancement mode metal oxide semiconductor or a depletion mode metal oxide semiconductor field effect transistor.

In another implementation, a method for forming a sensor includes forming a transistor comprising a transistor source, a transistor drain, and a transistor channel positioned between the transistor source and the transistor drain, forming a sensor element over the transistor channel, and forming a transistor gate of the transistor such that the sensor element is positioned between the transistor gate and the transistor channel. The sensor element is configured to generate an electric current when exposed to a stimulus and the sensor is configured such that a first electric current output by the transistor when the sensor element is exposed to the stimulus indifferent than a second electric current output by the transistor when the sensor element is not exposed to the stimulus.

The formation of the transistor may further forms a transistor wherein the electric current generated by the sensor element results from the exposure to the stimulus, the transistor drain is configured to have a first output when the transistor channel inverts and the sensor element is not being exposed to the stimulus, and the transistor drain has a second output when the transistor channel inverts and the sensor element is being exposed to the stimulus, wherein the second output is larger than the first output. The forming of the sensor element over the transistor channel may include attaching a photosensitive sensor element comprising a III-V semiconductor to a gate oxide such that the gate oxide is positioned between the photosensitive sensor element and the transistor channel. The forming of the transistor gate may form the transistor gate having a thickness and composition sufficient for passage of the stimulus through the transistor gate during operation of the transistor. The forming of the sensor element over the transistor channel may include attaching a chemically sensitive sensor element having at least one of a hydrophobic element or a hydrophilic element to a gate oxide such that the gate oxide is positioned between the chemically sensitive sensor element and the transistor channel, and the chemically sensitive sensor element is configured to generate a current when exposed to a chemical.

The forming of the sensor element over the transistor channel may further include attaching a III-V semiconductor to the gate oxide, and the sensor may be configured to sense a hydrophobic chemical reagent or a hydrophilic chemical reagent.

In an implementation, a method for operating a sensor having a transistor includes exposing a sensor element of the transistor to a stimulus, wherein the sensor element is electrically coupled to a transistor gate and positioned between the transistor gate and a transistor channel. While not exposing the sensor element to the stimulus, the method further includes inverting the transistor and reading a first output of a transistor drain of the transistor, exposing the sensor element to the stimulus and, while exposing the sensor element to the stimulus, inverting the transistor and readings second output of the transistor drain, wherein the second output is higher than the first output.

The exposing the sensor element to the stimulus may include exposing the sensor element to a first intensity or concentration of the stimulus, and the method further may further include exposing the sensor element to a second intensity or concentration of the stimulus, wherein the second intensity or concentration of the stimulus is higher than the first intensity or concentration of the stimulus and, while exposing the sensor element to the second intensity or concentration of the stimulus, inverting the transistor and reading a third output of the transistor drain, wherein the third output is higher than the second output. Each inversion of the transistor may include applying a threshold voltage to the transistor to invert the channel of the transistor. The exposing of the sensor element to the stimulus may expose the sensor element to photonic radiation.

### BRIEF DESCRIPTION OF THE DRAWINGS

The accompanying drawings, which are incorporated in, and constitute a part of this specification, illustrate implementations of the present teachings and, together with the description, serve to explain the principles of the disclosure. In the figures:

FIG. 1 is a schematic perspective depiction of a sensor in accordance with an implementation of the present teachings.

FIG. 2 is a graph depicting various operational characteristics that may be exhibited by a sensor implemented in accordance with the present teachings.

FIG. 3 is a cross section of an in-process structure that may be formed during a manufacturing process in accordance with the present teachings.

FIG. 4 depicts the FIG. 3 structure after each etch.

FIG. 5 depicts the FIG. 4 structure during a dopant implant.

FIG. 6 depicts the FIG. 5 structure after forming a mask to expose a portion of a field oxide region.

FIG. 7 depicts the FIG. 6 structure after an etch, the formation of a gate oxide layer, and the formation of a mask.

FIG. 8 depicts the FIG. 7 structure after formation of a sensor element.

FIG. 9 depicts the FIG. 8 structure after formation of device contacts and a transistor gate.

It should be noted that some details of the figures have been simplified and are drawn to facilitate understanding of the present teachings rather than to maintain strict structural accuracy, detail, and scale.

### DETAILED DESCRIPTION

Reference will now be made in detail to exemplary implementations of the present teachings, examples of which are illustrated in the accompanying drawings. Wherever possible, the same reference numbers will be used throughout the drawings to refer to the same or like parts.

As discussed above, the formation of detectors and sensors may include wafer-level fabrication of a plurality of photodetector dies and a plurality of readout integrated circuit (ROIC) dies on separate semiconductor wafers. Subsequently, the wafers are diced and each photodetector die may be flip-chip mounted to a ROIC die. This die-level hybridization is a low-yield, costly, and complex process. Decreasing manufacturing costs and complexity is a goal of designers and manufacturers.

The present teachings include a sensor manufacturing process, and a resulting sensor device, that may simplify the fabrication of detectors and sensors such as photosensors, chemical-sensors, and other types of sensors compared to conventional designs and manufacturing techniques. Further, the sensor manufacturing process may provides less costly detector and/or sensor. While the present teachings are generally discussed herein relative to photosensors, it will be appreciated that that the concepts and manufacturing techniques described herein may be useful for chemical sensors and other types of sensors, depending on the composition of the sensor element and the stimulus to which the sensor element is sensitive. A “sensor element” may also be referred to herein as a nanomembrane, a sensor material, a photosensitive sensor element, or a chemically sensitive sensor element.

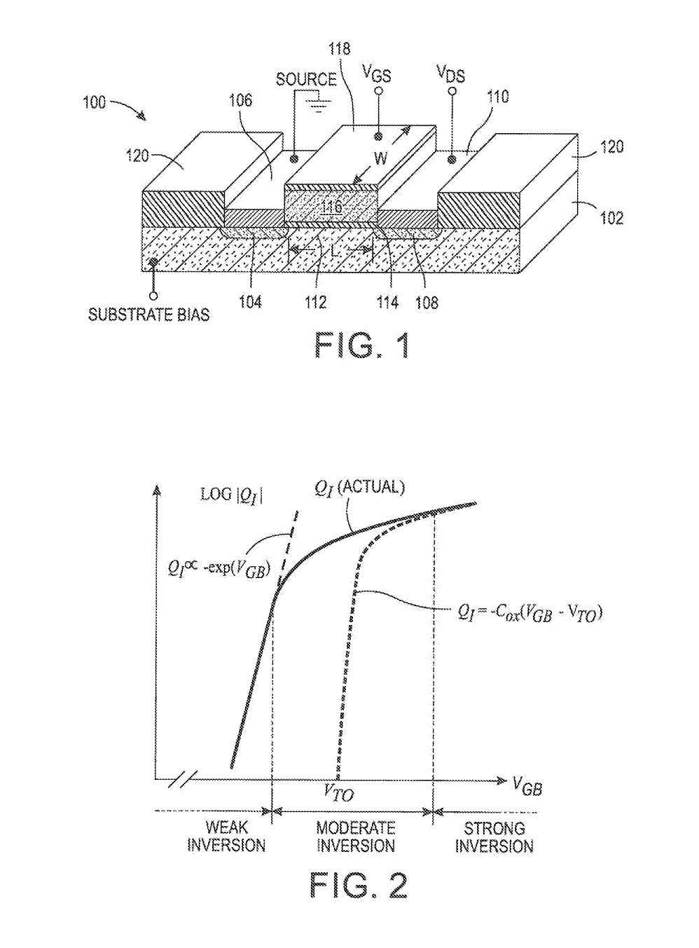

An implementation of a structure of the proposed device of the present teachings is depicted in FIG. 1, and is referred to herein as a GAte Modulation Enhanced (GAME) detector. As described below, the device as implemented in the FIG. 1 depiction operates generally as an enhancement mode N-channel metal oxide semiconductor field effect transistor (MOSFET), and further includes a sensor element (for example a photosensitive material that provides a photosensitive element) that influences the electrical operation of the device depending on the presence and intensity of the stimulus (for example photonic radiation) that reaches the sensor element. In an implementation as described below, the photosensitive element may be, for example, a III-V semiconductor material that is capacitively coupled with a gate of a transistor.

The GAME detector 100 of FIG. 1 includes a substrate 102 such as a semiconductor substrate, a transistor source region (i.e., transistor source or source) 104, a source contact 106, a transistor drain region (i.e., transistor drain or drain) 108, a drain contact 110, and a transistor channel region (i.e., transistor channel or channel) 112 positioned between the source 104 and drain 108. GAME detector 100 further includes a gate oxide layer (i.e., gate oxide) 114, sensor element (e.g., a photosensitive element, a chemically sensitive element, etc.) 116 that may physically contact the gate oxide 114, and a transistor gate (i.e., gate) 118 electrically coupled to, or in electrical contact with, the sensor element 116. The sensor element 116 is positioned between the gate 118 and the channel 112, and is directly electrically integrated with the other transistor elements. In FIG 1, the gate 118 is positioned over or overlies the channel 112. FIG. 1 further depicts dielectric or insulator 120 such as field oxide layer (i.e., field oxide) 120. The channel 112 has a width “W” and a length “L” as depicted. It will be appreciated that FIG. 1 depicts a simplified detail of a portion of a GAME detector 100 formed on or as part of a semiconductor wafer substrate assembly, which may include other structures and features not individually depleted for simplicity.

The sensor element 116 may be or include, for example, a III-V semiconductor or another material that generates a current or voltage when exposed to photonic radiation, and is capacitively coupled to the transistor gate 118. As depicted, the source contact 106 may be electrically coupled to ground, thereby grounding the source 104, and the gate 118 may be electrically coupled to a first voltage (e.g., V_{GS} or “gate-to-source voltage”). Additionally, the drain contact 110, and thus the drain 108, may be electrically coupled to a second voltage (e.g., V_{DS} or “drain-to-source voltage”).

As incident photonic radiation generates a current and/or voltage in the photosensitive sensor element 116, the V_{GS} varies an leads to a change in the drain current V_{DS}. The magnitude of the change depends on whether the transistor is biased in the sub-threshold regime, non-saturation or linear regime or the saturation regime. During operation, the photovoltage may be capacitively coupled to the gate of the transistor. In an enhancement mode (i.e., normally off) device implementation, the GAME detector 100 requires a minimum V_{GS} or threshold voltage “V_{T}” to electrically conduct across the channel 112 (i.e., turn on, invert, or trip the transistor). As known in the art, during inversion of the transistor channel 112, a sheet of positive or negative charge carriers are created that leads to electrical conduction through the channel 112 between the source 104 and the drain 108. In the absence of photonic radiation reaching, and electrically influencing the sensor element 116, the resulting drain current V_{DS} has a first value that may be measured by a readout circuit. In the presence of photonic radiation, the sensor element 116 becomes electrically active and generates a current. When the V_{T} is applied to the cell, the current generated by the sensor element increases the resulting V_{DS} compared to the V_{DS} when the stimulus is absent from the sensor element. Thus by applying the threshold voltage to the transistor and measuring the resulting V_{DS}, it may be determined whether the stimulus is present or absent on the sensor element 116.

The conversion of photovoltage into the current occurs in the MOSFET within the GAME detector. The operation region of the MOSFET can be controlled by the voltage of the gate terminal, V_{GS}, and the drain-source voltage, V_{DS}.

For example, if the MOSFET operates in saturation region, the output current of the GAME detector will be determined by the transconductance of the MOSFET, gₘ, at its operating point as shown below:

I_{DS}=gₘV_{gs}=gₘVₚₕ and gₘ=K′ₙ(W/L)(V_{gs}=V_{T})

where K′ₙ is the process transconductance parameter, W is the width, L is the channel length, V_{GS} is the gate bias voltage and V_{T} is the threshold voltage. The MOSFET transconductance depends on the device physical parameters, and is typically around ˜1 milliamp per volt (mA/V). If the photovoltage change is about 70 millivolts (mV), the output drain current change will be about 70 microamps (μA), which can be easily detected by a readout circuit.

On the other hand, the MOSFET can be in subthreshold region to enhance the detector responsivity. In this case, the GAME detector output current will be exponentially dependent on the gate photovoltage, V_{GS}, as shown in the graph of FIG. 2, which illustrates various operating regimes of the transistor of the GAME detector 100. The optimized operating point of the transistor may be determined by investigating the signal, noise, I_{ON}/I_{OFF} ratio and the speed of the GAME detector 100. The operation may be expressed as shown in the equation below:

$${I}_{DS} = {I}_{o} exp ( \frac{{V}_{GS}}{\frac{nKT}{q}} ) ( 1 - exp ( \frac{- {V}_{DS}}{\frac{nKT}{q}} ) )$$

where I₀ is the current coefficient, V_{GS}, is the gate voltage, V_{DS}, is the drain current, n is a scaling coefficient, and KT/q is the thermal potential. The relationship between output current and the photovoltage can also be calculated using the equation for subthreshold swing:

$$S = \frac{{V}_{{GS}_{2}} - {V}_{{GS}_{1}}}{{log}_{10} ( \frac{{I}_{{DS}_{2}}}{{I}_{{DS}_{1}}} )}$$

where S is the subthreshold swing. For example, the subthreshold swing of a typical MOSFET is around ˜70 mV/decade at room temperature, which means that if the photovoltage change is about 70 mV, the output drain current will change 10 times. This provides a superior sensitivity that is needed in variety of applications. At lower temperatures the subthreshold swing is smaller, which results in even greater sensitivity of the proposed GAME detector 100.

The electrical operation of the GAME detector 100 will be understood by one of ordinary skill in the art from the description herein.

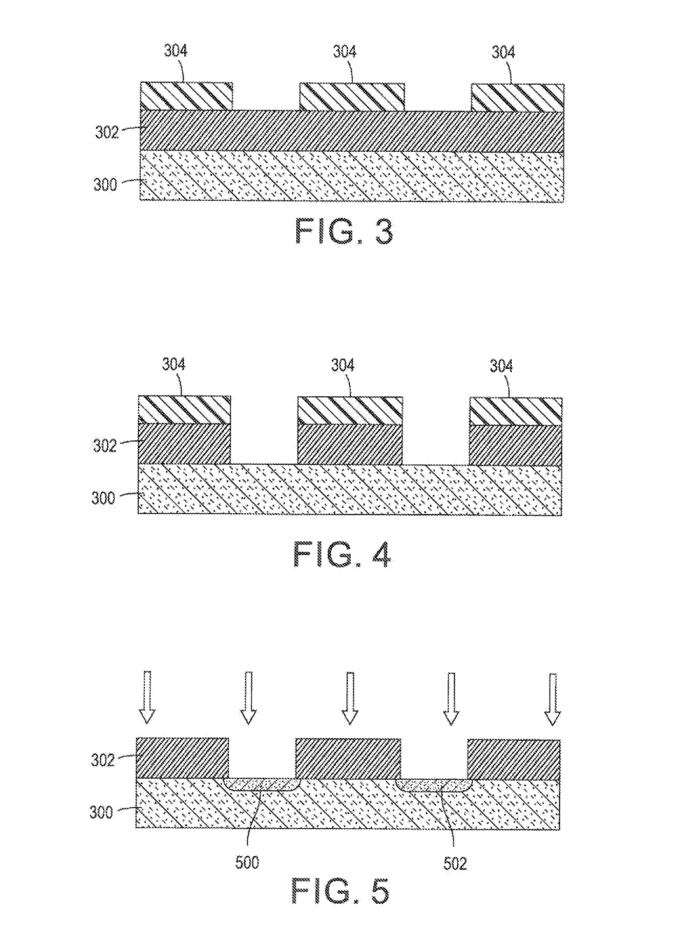

A method for forming a GAME detector, and various in-process structures according to an implementation of the present teachings, are depicted in FIGS. 3-8. It will be appreciated that various structures of an actual device in accordance with the present teachings may include other elements or features that, for clarity and/or simplicity, have not been depicted in the figures, and that various depicted elements and features may be removed or modified. Further, while FIGS. 3-8 depict the formation of a single GAME detector 100 including a single transistor, it will be appreciated that the device may be formed using microelectronic wafer fabrication techniques where hundreds or thousands of GAME detectors are simultaneously formed on a wafer substrate and then diced to form a hundreds or thousands of individual GAME detectors. Further, the formation of the structures of FIGS. 3-9 may also include the simultaneous (parallel) and/or sequential (serial) formation of supporting circuitry such as readout circuitry. The design and fabrication of transistor read and write circuitry is well known in the art and, for simplicity, is not described or depleted herein.

As depicted in FIG. 3, a deposited or grown insulator layer or dielectric layer 302, such as a field oxide layer 302, may be formed over a substrate 300 such as a semiconductor wafer substrate assembly. The substrate 300 may be, for example, a P-type substrate resulting in GAME detector including a P-channel MOSFET or the substrate 300 may be an N-type substrate resulting in GAME detector including an N-channel MOSFET. For simplicity of description, the text below describes the process with regard to the formation of a P-channel MOSFET, although the formation of an N-channel MOSFET will be apparent to one of ordinary skill in the art. The substrate 300 may be or include, for example, monocrystalline silicon, gallium arsenide, gallium antimonide, or another semiconductor substrate. As depicted in FIG. 3, the field oxide layer 302 may be patterned with a mask 304, for example, a patterned photoresist layer to cover and protect desired field oxide regions while leaving other field oxide regions exposed. It will be appreciated that one or more of the masks described herein may be a photoresist mask formed using photolithographic techniques known in the art, another type of mask, or combinations thereof.

Subsequently, the exposed field oxide 302 is removed to expose the substrate 300. The exposed field oxide 302 may be removed, for example, with a vertical anisotropic etch using an etchant that removes the field oxide 302 selective to the substrate 300 and the mask 304 (i.e., the etchant removes the field oxide 302 at a faster rate than it removes the substrate 300 and the mask 304) to result in a structure similar to that depicted in FIG. 4. Anisotropic oxide etches and etchants that are selective to semiconductor substrate 300, such as dry etches, are well known in the art. After etching the field oxide 302 to result in the FIG. 4 structure, the mask 304 may be removed.

Next, a blanket implant process of, for example, phosphorus may be performed to form the N-type transistor source 500 and the transistor drain 502 as depicted in FIG. 5. Dopant implant concentrations, depths, and diffusion applicable to conventional transistor formation may be employed. The source 500 and drain 502 are thus patterned by, and self-aligned with, the remaining field oxide 302.

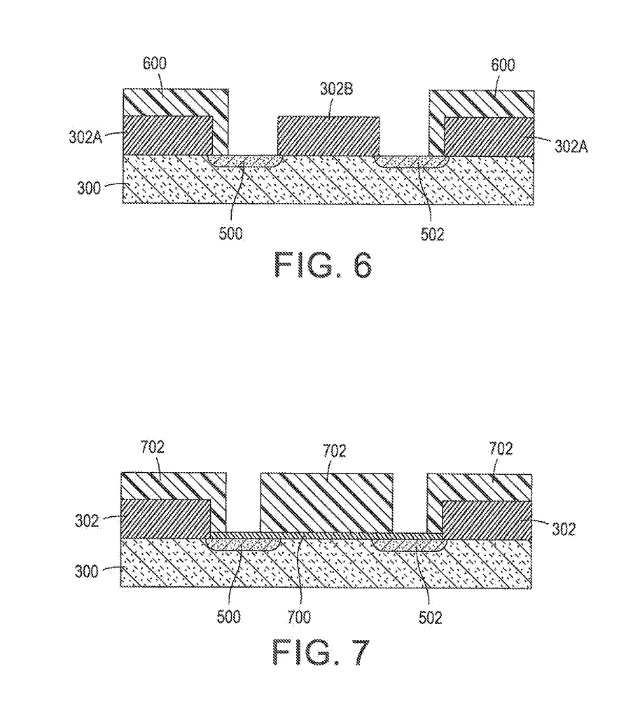

Next, as depicted in FIG. 6, a patterned mask 600 may be formed is cover first portions 302A of the field oxide 302 and to expose a second portion 302B of the field oxide 302, where the second portion 302B is positioned over and between the source 500 and the drain 502. Subsequently, an etch may be performed to remove the second portion 302B of the field oxide 302, then the patterned mask 600 is removed to expose the substrate 300 between the remaining first portions 302A of the field oxide 302. A gate oxide layer 700 as depicted in FIG. 7 is then grown or otherwise formed on the exposed portion of the substrate 300 using known manufacturing techniques. Subsequently, a patterned mask 702 is formed to expose portions of the gate oxide 700 that overlie the source 500 and drain 502 where a source contact and a drain contact respectively will be formed. The exposed gate oxide 700 is etched to expose the underlying substrate 300, then the mask 702 is removed.

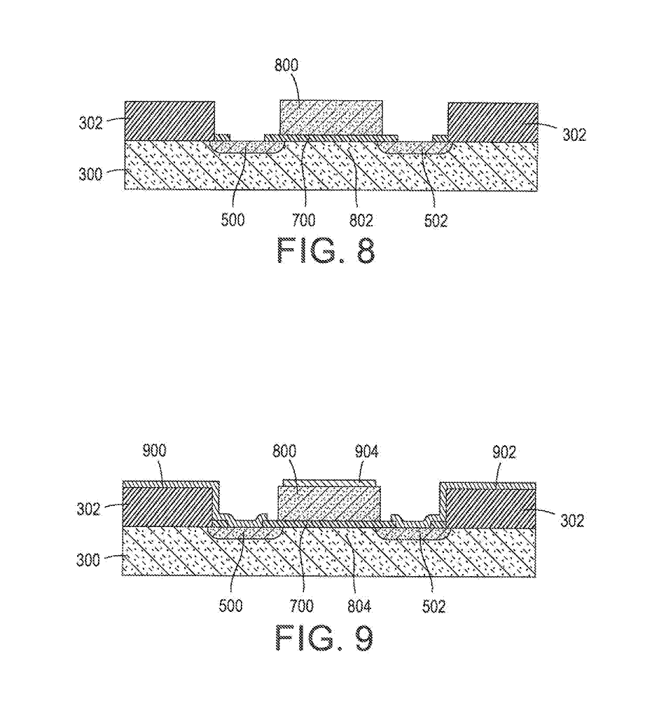

Next, a sensor element 800 is provided over a transistor channel region 802 as depicted in FIG. 8, where the channel region 802 is positioned between the source 500 and the drain 502 in accordance with known transistor design. The sensor element 800 may be centered over the channel region 802 as depicted.

In an implementation, the sensor element 800 may have a thickness of from about 1 nanometer (nm) to about 50 microns. The thickness may depend, for example, on an absorption coefficient Of the material used to form the sensor element 800.

In an implementation, the sensor layer 800 may be a photosensitive layer that is or includes a III-V semiconductor material that generates a photovoltage (i.e., an electric voltage produced by the sensor layer when exposed to, and induced by the action of, photonic radiation). In another implementation, the sensor layer 800 may be or include a material that generates a current or voltage when exposed to a stimulus or stimuli different from photonic radiation, such as a chemical sensor that generates a current or voltage when exposed to one or more chemicals. In one implementation, the sensor layer 800 may be a chemical sensor such as a III-V semiconductor material that is, or has been treated to be, hydrophilic or hydrophobic to generate a voltage when exposed to a chemical such as a chemical reagent, for example, a bio-chemical hydrophilic reagent or a bio-chemical hydrophobic reagent. Other suitable chemical sensor materials that generate a voltage in the presence of one or more chemicals, and the chemicals sensed by the other chemical sensor materials, are known in the art and contemplated for use with the present implementations.

In one method for providing the patterned sensor element 800, patterned sensor element 800, such as a III-V semiconductor material, may be grown, for example as an epitaxial layer, on a separate growth substrate, such as a semiconductor wafer, and then transferred from the growth substrate to substrate 300. In an implementation, a plurality of patterned sensor elements 800 are grown on the growth substrate and then simultaneously transferred to the wafer substrate 300 where the plurality of GAME detectors 100 are being formed. In one implementation, the one or more sensor elements 800 may be transferred using a transfer layer such as a polydimethylsiloxane (PDMS) transfer layer or another transfer layer. In another process, a blanket layer of sensor element material may be formed on a transfer layer and then segmented using an etch or a dicing process to form a plurality of sensor elements 800. The sensor elements 800 may then be transferred to the gate oxide 700.

Next, the source contact 900, the drain contact 902, and the transistor gate 904 may be formed, for example, as depicted in FIG. 9. The source contact 900, the drain contact 902, and the transistor gate 904 may be simultaneously formed, for example, by forming a blanket conductive layer, such as a metal and/or a metal alloy layer, which may be subsequently patterned using a mask (not individually depicted for simplicity) and an etch process according to techniques known in the art. The completed source contact 900, drain contact 902, and transistor gate 904 may have a thickness of from about 100 nm to about 100 microns. The transistor gate 904 may have a thickness (i.e., may be sufficiently thin), a composition, and/or physical characteristics (e.g., translucency, permeability, etc.) such that a sufficient amount of the stimulus (e.g., chemical or photonic radiation) passes through the transistor gate 904 and generates a voltage within the sensor element 800. In another implementation, the stimulus may enter the sensor element 800 at the exposed vertical edges and, if present, the top surface that is exposed around the transistor gate 904. Additionally, the substrate 300, the gate oxide 700, and/or the source contact 900 and the drain contact 902 may be sufficiently permeable for the stimulus to pass through and reach the sensor element 800 to generate a current.

As discussed above, the voltage generated within the sensor element 800 in the presence of the stimulus alters the resulting drain current which is measured by a ROIC through the drain contact 110. The V_{DS} that results from the application of V_{T} to the transistor provides an indication of whether the stimulus is being applied to the sensor element 800. Additionally, an intensity of a stimulus may result in different current levels being generated by the sensor element 800 which, in turn, results in different V_{DS} values. Through experimentation or modeling, the amplitude of the measured V_{DS} may provide an indication of the intensity or concentration of the stimulus to which the sensor element 800 is being subjected, with lower values indicated that little or no stimulus is reaching the sensor element and high values indicating a large amount of stimulus is reaching the sensor element.

Subsequently, after forming a structure similar to that depicted in FIG. 9, additional wafer processing may be performed, for example, the formation of supporting circuitry such as read/write circuitry, forming passivation layers, and device packaging to form a completed GAME detector.

It will be appreciated that while the process above and depicted in FIGS. 3-9 is described as a series of acts or events, the present teachings are not limited by the ordering of such acts or events. Further, the process described is an exemplary implementation for forming a GAME detector, and other process flows and additional method acts to implement a GAME detector are contemplated.

The completed structure described herein is in the form of an enhancement mode MOSFET, but it will be appreciated that the GAME detector may be or include one or more other types of devices such as other types of transistor devices. These one or more devices may be or include N-channel or P-channel metal oxide semiconductor (MOS) devices, complementary MOS devices, bipolar junction transistor (BJT) devices including NPN, PNP, etc., high-electron-mobility transistors (HEMTs), heterojunction bipolar transistors (HBTs), other field effect transistors (FETs), etc. The devices may be formed to include, semiconductor materials such as silicon (e.g., monocrystalline or polycrystalline silicon), gallium (e.g., gallium arsenide GaAs, gallium antimonide GaSb), and/or indium (e.g., indium arsenide InAs, indium phosphide InP, indium antimonide InSb). The devices may further include materials such as graphene, molybdenum disulfide (MoS₂), molybdenum diselenide (MoSe₂), gallium nitride (GaN), aluminum gallium nitride (AlGaN), ultra-wide bandgap semiconductors, etc.

Notwithstanding that the numerical ranges and parameters setting forth the broad scope of the present teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less than 10” can assume negative values, e.g., −1, −2, 3, −10; −20, −30, etc.

While the present teachings have been illustrated with respect to one or more implementations, alterations and/or modifications can be made to the illustrated examples without departing from the spirit and scope of the appended claims. For example, it will be appreciated that while the process is described as a series of acts or events, the present teachings are not limited by the ordering of such acts or events. Some acts may occur in different orders and/or concurrently with other acts or events apart from those described herein. Also, not all process stages may be required to implement a methodology in accordance with one or more aspects or implementations of the present teachings. It will be appreciated that structural components and/or processing stages can be added or existing structural components and/or processing stages can be removed or modified. Further, one or more of the acts depicted herein may be carried out in one or more separate acts, and/or phases. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. As used herein, the term “one or more of” with respect to a listing of items such as, for example, A and B, means A alone, B alone, or A and B. The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated implementation. Finally, “exemplary” indicates the description is used as an example, rather than implying that it is an ideal. Other implementations of the present teachings will be apparent to those skilled in the art from consideration of the specification and practice of the disclosure herein. It is intended that the specification and examples be considered as exemplary only, with a true scope and spirit of the present teachings being indicated by the following claims.

Terms of relative position as used in this application are defined based on a plane parallel to the conventional plane or working surface of a workpiece, regardless of the orientation of the workpiece. The term “horizontal” or “lateral” as used in this application is defined as a plane parallel to the conventional plane or working surface of a workpiece, regardless of the orientation of the workpiece. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the workpiece, regardless of the orientation of the workpiece.

1. A sensor, comprising:
a transistor comprising a transistor source, a transistor drain, a transistor channel positioned between the transistor source and the transistor drain, and transistor gate positioned over the transistor channel; and
a sensor element positioned between the transistor gate and the transistor channel, wherein:
the sensor element is configured to generate an electric current when exposed to a stimulus; and
the sensor is configured such that first electric current output by the transistor when the sensor element is exposed to the stimulus is different than a second electric current output by the transistor when the sensor element is not exposed to the stimulus.

2. The sensor of claim 1, wherein:
the electric current generated by the sensor element results from the exposure to the stimulus;
the transistor drain has a first output when a threshold voltage is applied to the transistor and the sensor element is not being exposed to the stimulus; and
the transistor drain has a second output when the threshold voltage is applied to the transistor and the sensor element is being exposed to the stimulus, wherein the second output is larger than the first output.

3. The sensor of claim 1, wherein the sensor element is a III-V semiconductor and the sensor is configured to sense photonic radiation.

4. The sensor of claim 1, wherein the sensor element has a thickness of from 10 nanometers to 50 microns.

5. The sensor of claim 4, wherein the transistor gate has a thickness of from 1 nanometer to 10 microns.

6. The sensor according to claim 1, wherein the transistor gate is configured for passage of the stimulus therethrough during operation of the transistor.

7. The sensor according to claim 1, wherein the sensor element comprises at least one of a hydrophilic sensor element or a hydrophobic sensor element and the sensor is configured to sense a chemical.

8. The sensor of claim 7, wherein the sensor element is a III-V semiconductor and the sensor is configured to sense a hydrophobic chemical reagent or a hydrophilic chemical reagent.

9. The sensor according to claim 1, wherein the transistor is an enhancement mode metal oxide semiconductor field effect transistor.

10. The sensor according to claim 1, wherein the transistor is a depletion mode metal oxide semiconductor field effect transistor.

11. A method for forming a sensor, comprising:
forming a transistor comprising a transistor source, a transistor drain, and a transistor channel positioned between the transistor source and the transistor drain;
forming a sensor element over the transistor channel; and
forming a transistor gate of the transistor such that the sensor element is positioned between the transistor gate and the transistor channel, wherein:
the sensor element is configured to generate an electric current when exposed to a stimulus; and
the sensor is configured such that a first electric current output by the transistor when the sensor element is exposed to the stimulus is different than a second electric current output by the transistor when the sensor element is not exposed to the stimulus.

12. The method of claim 11, wherein the formation of the transistor further forms a transistor wherein:
the electric current generated by the sensor element results from the exposure to the stimulus;
the transistor drain is configured to have a first output when the transistor channel inverts and the sensor element is not being exposed to the stimulus; and
the transistor drain has a second output when the transistor channel inverts and the sensor element is being exposed to the stimulus, wherein the second output is larger than the first output.

13. The method of claim 11, wherein the forming of the sensor element over the transistor channel comprises attaching a photosensitive sensor element comprising a III-V semiconductor to a gate oxide such that the gate oxide is positioned between the photosensitive sensor element and the transistor channel.

14. The method of claim 11, wherein the forming of the transistor gate forms the transistor gate having a thickness and composition sufficient for passage of the stimulus through the transistor gate during operation of the transistor.

15. The method of claim 11, wherein the forming of the sensor element over the transistor channel comprises attaching a chemically sensitive sensor element comprising at least one of a hydrophobic element or a hydrophilic element to a gate oxide such that the gate oxide is positioned between the chemically sensitive sensor element and the transistor channel, and the chemically sensitive sensor element is configured to generate a current when exposed to a chemical.

16. The method of claim 15, wherein:
the forming of the sensor element over the transistor channel further comprises attaching a III-V semiconductor to the gate oxide; and
the sensor is configured to sense a hydrophobic chemical reagent or a hydrophilic chemical reagent.

17. A method for operating a sensor having a transistor, the method comprising:
exposing a sensor element of the transistor to a stimulus, wherein the sensor element is electrically coupled to a transistor gate and positioned between the transistor gate and a transistor channel;
while not exposing the sensor element to the stimulus, inverting the transistor and reading a first output of a transistor drain of the transistor;
exposing the sensor element to the stimulus; and
while exposing the sensor element to the stimulus, inverting the transistor and reading a second output of the transistor drain, wherein the second output is higher than the first output.

18. The method of claim 17, wherein the exposing the sensor element to the stimulus comprises exposing the sensor element to a first intensity or concentration of the stimulus, and the method further comprises:
exposing the sensor element to a second intensity or concentration of the stimulus, wherein the second intensity or concentration of the stimulus is higher than the first intensity or concentration of the stimulus; and
while exposing the sensor element to the second intensity or concentration of the stimulus, inverting the transistor and reading a third output of the transistor drain, wherein the third output is higher than the second output.

19. The method of claim 18, wherein each inversion of the transistor comprises applying a threshold voltage to the transistor to invert the channel of the transistor.

20. The method of claim 16, wherein the exposing of the sensor element to the stimulus exposes the sensor element to photonic radiation.
